(19) United States
(12) Patent Application Publication
(10) Pub. No.: US 2017/0154828 A1
(43) Pub. Date: Jun. 1, 2017

(54) ADAPTIVE TCB BY DATA FEED FORWARD

(71) Applicant: INTEL CORPORATION, Santa Clara, CA (US)

(72) Inventors: Timothy A. GOSSELIN, Phoenix, AZ (US); Patrick NARDI, Scottsdale, AZ (US); Kartik SRINIVASAN, Gilbert, AZ (US); Amram EITAN, Scottsdale, AZ (US); Ji Yong PARK, Chandler, AZ (US); Christopher L. RUMER, Chandler, AZ (US); George S. KOSTIEW, Queen Creek, AZ (US)

(21) Appl. No.: 14/953,779

(22) Filed: Nov. 30, 2015

(51) Int. Cl. H01L 21/66; B23K 20/02; B23K 20/00; H01L 23/00

(52) U.S. Cl. CPC H01L 22/12; H01L 24/75; H01L 24/14; B23K 20/023; B23K 20/002; H01L 2924/351

(57) ABSTRACT

A method and machine-readable medium including non-transitory program instructions that when executed by a processor cause the processor to perform a method including measuring at least one parameter of a substrate or a die; and establishing or modifying a thermal compression bonding recipe based on the at least one parameter, wherein the thermal compression bonding recipe is operable for thermal compression bonding of the die and the substrate. A thermal compression bonding tool including a pedestal operable to hold a substrate during a thermal compression bonding process and a bond head operable to engage a die, the tool including a controller machine readable instructions to process a substrate and a die combination, the instructions including an algorithm to implement or modify a thermal compression bonding process based on a parameter of a substrate or die.

### BACKGROUND

Field

Integrated circuit packaging.

Description of Related Art

Thermal compression bonding (TCB) is becoming a prevalent technology as package thickness and interconnect size/pitch decrease. In TCB, as practiced today, a single recipe is selected to achieve good yield/quality across a specified range of incoming substrate/die materials. Most substrate/die combinations have a process window where all bumps can be contacted (preventing non-contact opens (NCO) without causing solder bump bridging (SBB)), but each substrate can have a unique window between these failure modes. A typical TCB process recipe is selected to work across the largest range of substrate/die combinations. Substrates/die not fitting into that specified range must either be taken as yield loss in assembly or screened out before bonding.

### BRIEF DESCRIPTION OF THE DRAWINGS

FIG. 1A shows a graphical representation of a TCB process to, for example, attach solder connections between a die and a package substrate.

FIG. 1B shows a graphical representation of a TCB process for two different combinations of die and package substrate (unit 1 and unit 2), wherein each die and package substrate have individual parameters.

FIG. 2 presents a flow chart of a method of operation, particularly the operation of TCB tool to assemble a substrate and die using TCB.

FIG. 3 shows exemplary representations of substrate xy slopes and indicates CTV and BTV measurements.

FIG. 4 shows what can be done if the TCB tool is provided parameter data about an x-y plane that describes a top surface of the substrate (CTV or BTV).

FIG. 5 shows a simulation of TCB collapse targets for different substrate BTVs and mean bump heights.

FIG. 6 shows how the fitting of experimental data regarding die and substrate parameters into a second order function of incoming BTV value and bump height mean.

### DETAILED DESCRIPTION

As package complexity increases and/or feature size decreases, the acceptable window for successful TCB process becomes smaller and smaller. This means more expensive manufacturing processes for the die/substrate and/or increased cost due to substrate/die yield loss before assembly. However, typical TCB equipment has potential to adjust the process/recipe to the specific die/substrate combination if the appropriate measurements/parameters are fed-forward to the TCB tool and the tool has the logic to calculate/select the correct settings. This has the potential to create cost savings by widening the spec limits on incoming materials and improving the upstream yields.

In one embodiment, an algorithm or a set of algorithms is generated and applied to a TCP tool process recipe to establish or to adjust a TCB recipe setting to those specifically needed to create a good unit for a particular substrate/die combination (e.g., acceptable attachment of a die to a substrate). By identifying (marking), pre-measuring, and storing key parameters before bonding, a TCB tool can subsequently call up those parameter values, or pre-calculated recipe settings using the unit specific marking and calculate the best settings for each bond.

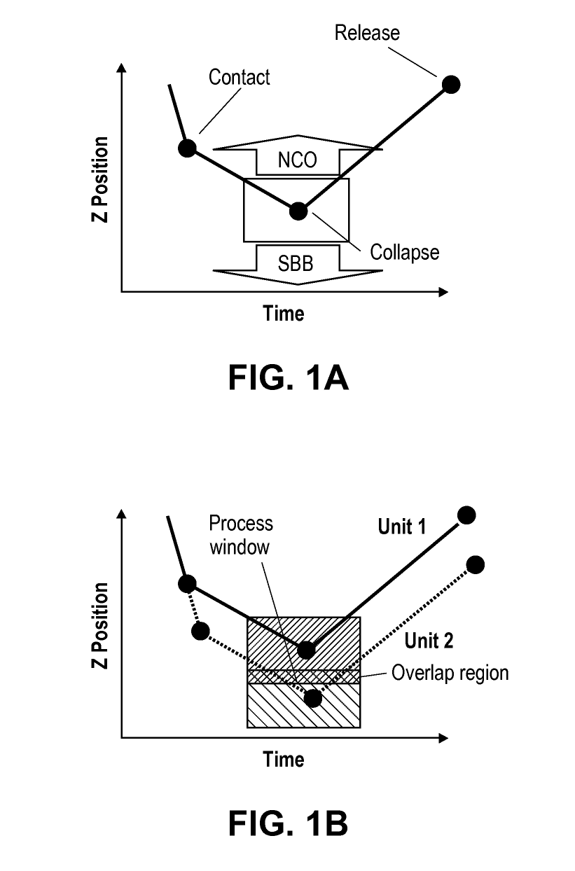

FIG. 1A shows a graphical representation of a TCB process to, for example, attach solder connections between a die and a package substrate. In one embodiment, a process recipe requires a certain displacement or force by a bonding tool on, for example, a die when the contact points of a die are aligned with solder pads of the substrate with solder being on one or both of the contact points and solder pads. FIG. 1A shows that as the bonding tool is displaced in a z-direction downward, contact is made between the die and the substrate and displacement continues beyond the initial point of contact to a point that targets an acceptable attachment window to minimize NCO or SBB.

FIG. 1B shows a graphical representation of a TCB process for two different combinations of die and package substrate (unit 1 and unit 2), wherein each die and package substrate have individual parameters (e.g., xy-planarity, solder bump height). FIG. 1B shows that due to parameter differences, an overlap region between acceptable attachment windows can be small.

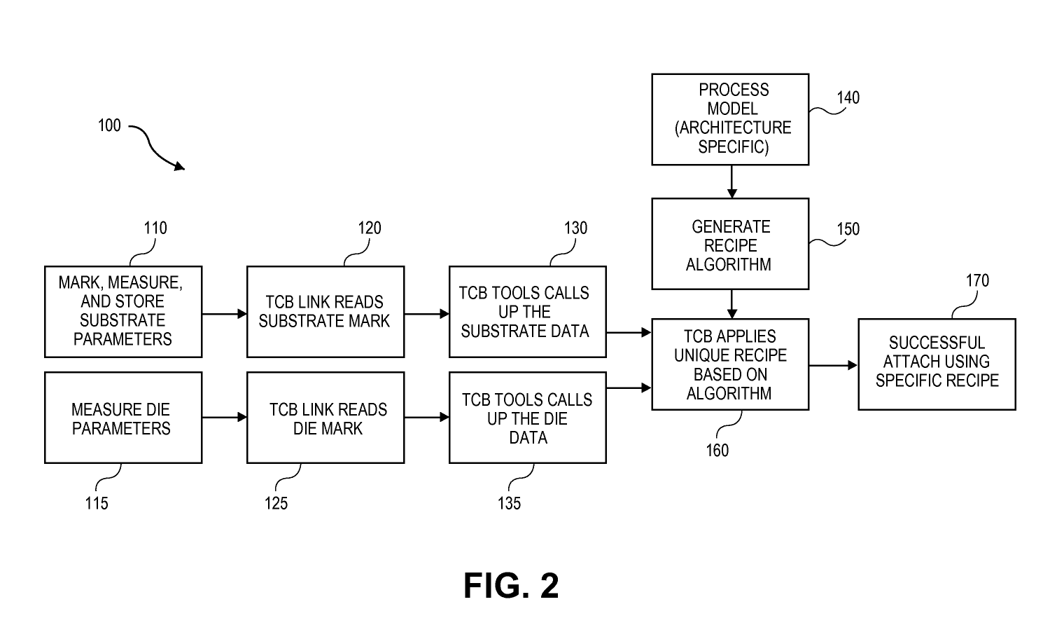

FIG. 2 presents a flow chart of a method of operation, particularly the operation of a TCB tool to assemble a substrate and die using TCB. The method will be described in terms of an automated process where a processor collects data and makes such data available to a TCB tool through machine-readable instructions (e.g., a computer program) stored in the processor or accessible by the processor. The TCB tools contains a controller that has an algorithm contained therein for processing a substrate and die and such data from the processor is input to the algorithm and appropriate parameters are generated and applied in a TCB process. In another embodiment, a TCB process model may be established and the data provided by processor to TCB is used by the TCB to offset the process model. Representatively, the process model may be set to a displacement of 15 microns (μm). The data from the processor regarding parameters of a particular substrate or die may require that the displacement be offset, such as offset 2 μm less (13 μm) or more (17 μm).

In one embodiment, a processor that collects data for a TCB tool contains non-transient machine-readable instructions that when executed collects and/or generates substrate and die parameters for which a TCB can implements a TCB process recipe to a particular substrate and die combination (e.g., through its own non-transitory machine-readable medium instructions). Referring to FIG. 2, method 100 includes marking, measuring and storing parameters specific to a substrate in a memory associated with the controller (block 110). Marking refers to obtaining identifying information of the substrate, such as a previously established identification number associated with the substrate. Substrate parameters representatively include substrate thickness variation (CTV or BTV) or xy-planarity or slope, and bump height of, for example, solder bumps. Method 100 also includes marking, measuring and storing die parameters by the controller for a die that will be associated with the substrate marked in block 110 (block 115). In one embodiment, measuring die parameters includes measuring xy-planarity of the die.

Following the marking, measuring and storing of substrate and die parameters, method 100 provides that a TCB link will read a mark on a substrate (block 120) and a mark on a die (block 125). A TCB controller contains a process model in the form of non-transitory machine-readable instructions to process a substrate and die combination (e.g., to combine a substrate and die through a TCB process) (block 140). In one embodiment, the TCB controller also includes an algorithm to implement or modify the TCB process based on particular substrate and die parameters. According to method 100, the TCB controller generates a process recipe for a particular substrate/die combination (block 150). The recipe is then applied to combine a particular substrate and die (block 160) and a successful attachment of the two units is obtained (block 170).

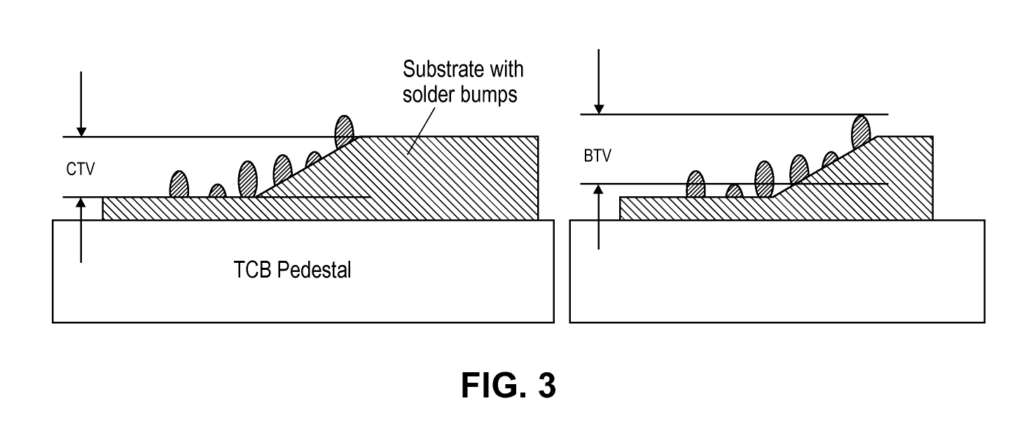

Substrate thickness variation is inherent to a substrate manufacturing process. When it occurs within a single die area that variation it is called CTV or BTV as demonstrated in FIG. 3. CTV and BTV are measured with the substrate pulled flat under vacuum and are the TCB analog of ‘coplanarity’ used in traditional reflow processes. The difference between parameters is that CTV is calculated using the substrate surface and BTV uses a top of the substrate bump (as viewed).

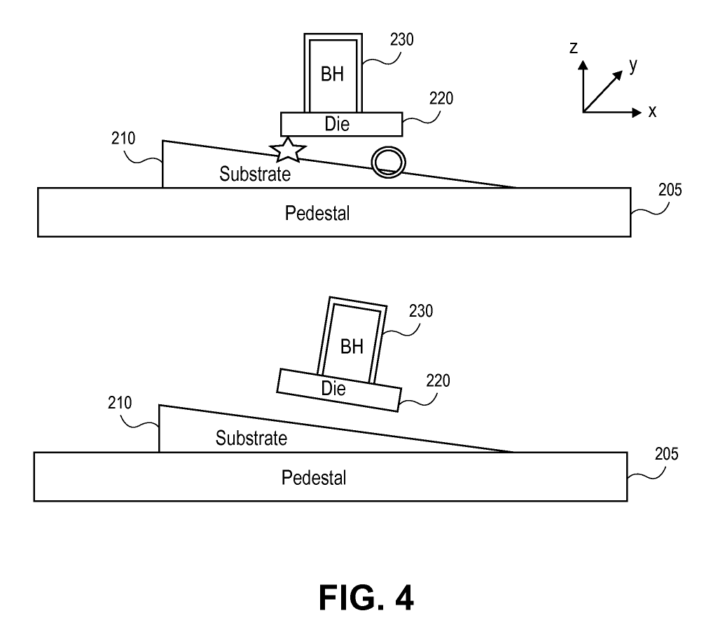

FIG. 4 shows what can be done if the TCB tool is provided parameter data about an x-y plane that describes a top surface of the substrate (CTV or BTV). FIG. 4 shows substrate a side view of a tool pedestal having a substrate thereon. Substrate 210 has a sloped z-height in an x-direction as viewed with a tallest z-height or thickness on a left side of the substrate as viewed. In a case where the x-y parameter data was not considered by the TCB process recipe, bond head 230 of the TCB tool is parallel to pedestal 205 and not necessarily a surface of substrate 210. This creates a risk of NCO (right) or SBB (left) upon displacement. If the substrate plane parameter is known ahead of time, bond head 230 can be adjusted to be parallel to the substrate by, for example, adding/subtracting an angular offset to a normal state (parallel to the pedestal). Such an adjustment reduces a risk of assembly defects as seen in FIG. 4 (bottom).

Eliminating a tilt contribution to thickness variation has the effect of allowing a larger specification window at substrate suppliers. In one example, an actual substrate had about 21 μm of variation, but removing a tilt component gave it an effective variation of about 15 μm that would be allowable for healthy TCB process. Besides yield improvement, an ability to better control the net die tilt relative to top substrate surface will also help enable capillary underfill (CUF) at finer C4 pitches/chip gaps by improving the uniformity of the epoxy flow front.

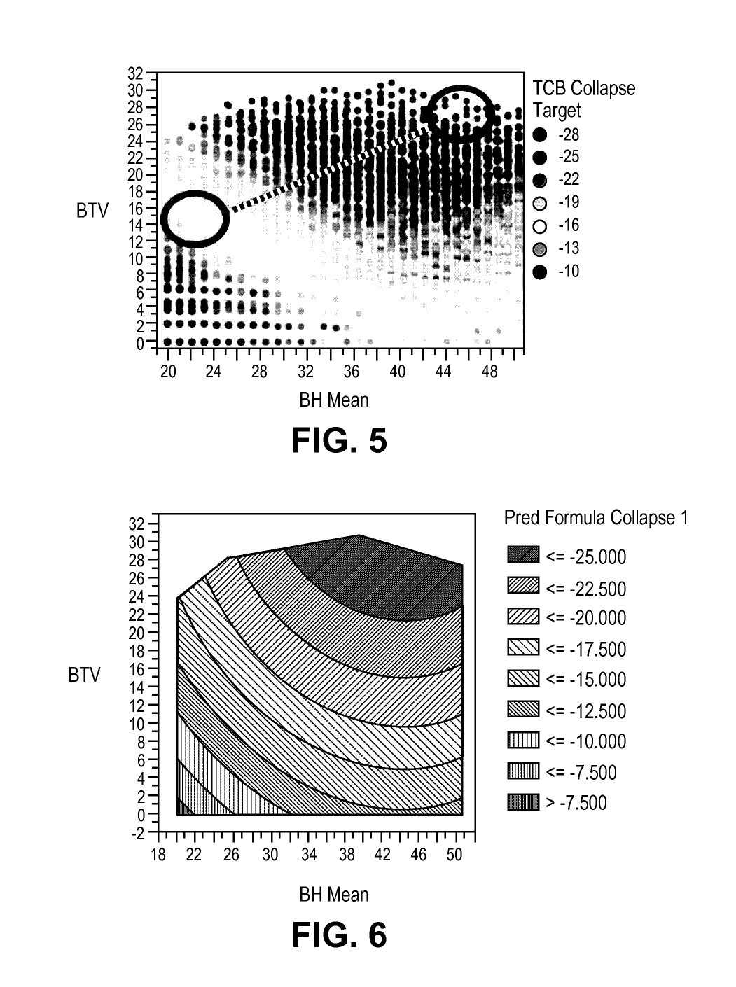

An additional process margin that can be gained even after correcting for a parameter of thickness variation. By applying an algorithm to incoming data, a TCB recipe can be adjusted to accommodate a larger range of incoming substrate variations. FIG. 5 shows a simulation of TCB collapse targets for different substrate BTVs and mean bump heights. Simulation shows a substrate with a 44 μm mean height and 28 μm BTV can be assembled using a TCB recipe with about 28 μm of collapse, but that same recipe would not work for a unit with only a 22 μm bump height as the die would bottom-out on the substrate surface. In the case where the latter units bump height and the BTV are known in advance, a collapse can be predicted at about 14 μm instead of the 28 μm used on the former unit. FIG. 6 shows how the simulation/experimental data can be fit to a simple function of key metrics (here second order function of incoming BTV value and bump height mean).

The above description of illustrated implementations, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
measuring at least one parameter of a substrate or a die; and
establishing or modifying a thermal compression bonding recipe based on the at least one parameter, wherein the thermal compression bonding recipe is operable for thermal compression bonding of the die and the substrate.

2. The method of claim 1, wherein the parameter of the substrate is a substrate thickness variation, planarity or bump height of solder bumps on the substrate.

3. The method of claim 1, wherein the parameter of the die comprises an xy-planarity of the die.

4. The method of claim 1, further comprising measuring at least one parameter of the other of the substrate or the die and establishing or modifying a thermal compression bonding recipe based on the at least one parameter of each of the die and the substrate.

5. The method of claim 1, wherein after establishing or modifying a thermal compression bonding recipe, thermal compression bonding the die to the substrate based on the recipe.

6. The method of claim 1, wherein the one parameter comprises an xy planarity of the substrate and establishing or modifying a thermal compression bonding recipe comprises adjusting a bond head of a thermal compression bonding tool to be parallel to the substrate.

7. A thermal compression bonding tool comprising a pedestal operable to hold a substrate during a thermal compression bonding process and a bond head operable to engage a die, the tool comprising a controller machine readable instructions to process a substrate and a die combination, the instructions comprising an algorithm to implement or modify a thermal compression bonding process based on a parameter of a substrate or die.

8. The tool of claim 7, wherein the parameter of the die comprises an xy-planarity of the die.

9. The tool of claim 7, wherein the algorithm modifies a thermal compression bonding recipe based on at least one parameter of each of the die and the substrate.

10. The tool of claim 7, wherein after establishing or modifying a thermal compression bonding recipe, thermal compression bonding the die to the substrate based on the recipe.

11. A machine-readable medium including non-transitory program instructions that when executed by a processor cause the processor to perform a method comprising:
measuring at least one parameter of a substrate or a die; and
establishing or modifying a thermal compression bonding recipe based on the at least one parameter, wherein the thermal compression bonding recipe is operable for thermal compression bonding of the die and the substrate.

12. The machine-readable medium of claim 11, wherein the parameter of the substrate is a substrate thickness variation, planarity or bump height of solder bumps on the substrate.

13. The machine-readable medium of claim 11, wherein the parameter of the die comprises an xy-planarity of the die.

14. The machine-readable medium of claim 11, wherein the method further comprises measuring at least one parameter of the other of the substrate or the die and establishing or modifying a thermal compression bonding recipe based on the at least one parameter of each of the die and the substrate.

15. The machine-readable medium of claim 11, wherein after establishing or modifying a thermal compression bonding recipe, the method further comprises thermal compression bonding the die to the substrate based on the recipe.

16. The machine-readable medium of claim 11, wherein the one parameter comprises an xy planarity of the substrate and establishing or modifying a thermal compression bonding recipe comprises adjusting a bond head of a thermal compression bonding tool to be parallel to the substrate.
